(19) United States
(12) Patent Application Publication
(10) Pub. No.: US 2002/0019143 A1
(43) Pub. Date: Feb. 14, 2002

(54) FARICATION OF HIGH QUALITY OXIDES BY CONTROLLING SPACING BETWEEN SEMICONDUCTOR WAFERS DURING PROCESSING

(76) Inventors: HYEON-SEAG KIM, SUNNYVALE, CA (US); QXIAO-YU LI, SAN JOSE, CA (US); SUNIL D. MEHTA, SAN JOSE, CA (US)

Correspondence Address: MONICA H CHOI, P O BOX 3424, DUBLIN, OH, 430160204

(21) Appl. No.: 09/276,068

(22) Filed: Mar. 25, 1999

(51) Int. Cl. H01L 21/31; H01L 21/469

(52) U.S. Cl. 438/770; 438/239

(57) ABSTRACT

The present invention is a method for fabricating high quality oxides on a plurality of semiconductor wafers by proper positioning of those semiconductor wafers with respect to each other within a wafer cassette for processing within a bath. Each of the plurality of semiconductor wafers has a predetermined diameter. The method of the present invention includes a step of placing the plurality of semiconductor wafers in a wafer cassette that holds the plurality of semiconductor wafers in a stack configuration. According to the present invention, the plurality of semiconductor wafers within the wafer cassette are spaced with a respective predetermined distance between any two adjacent semiconductor wafers such that a respective ratio of the respective predetermined distance to the predetermined diameter of a semiconductor wafer is at least 0.12. The wafer cassette holding the plurality of semiconductor wafers is then placed within a bath having a liquid agent that processes oxides, such as etching the oxides, on the plurality of semiconductor wafers. Separating the plurality of semiconductor wafers by at least a predetermined distance from each other within the wafer cassette for processing within a bath ensures that proper amounts of chemicals within the liquid agent of the bath reach all areas of the semiconductor wafers for a thorough processing of the oxides on the semiconductor wafers. With such separation of the plurality of semiconductor wafers, oxides have lower failure rate, higher charge accumulation before breakdown, and higher breakdown voltage.

### TECHNICAL FIELD

This invention relates to processing of oxide regions during integrated circuit fabrication, and more particularly, to a method for fabricating high quality oxide regions by controlling spacing between semiconductor wafers during processing of the oxide regions.

### BACKGROUND OF THE INVENTION

Oxides which form part of capacitors or MOSFETs (Metal Oxide Semiconductor Field Effect Transistors) are a common part of integrated circuits. The background of the present invention is described with respect to oxides for capacitors. However, the present invention may be advantageously used for fabrication of oxides in any type of integrated circuit device, as would be apparent to one of ordinary skill in the art of integrated circuit fabrication from the description herein.

Referring to FIG. 1A, a top view of a capacitor 102 formed on a semiconductor wafer 104 is shown. Referring to FIG. 1B, a cross sectional view of the capacitor 102 of FIG. 1A along line A-A is shown. A diffusion region 106 which may be doped with n-type dopants or p-type dopants is formed within the semiconductor wafer 104, as known to one of ordinary skill in the art of integrated circuit fabrication. An oxide 108 of the capacitor 102 is formed on top of the diffusion region 106, and a polysilicon layer 110 is formed on top of the oxide 108. A buffer oxide layer 112 covers the semiconductor wafer 104.

Field oxide regions 113 surround the capacitor 102 to isolate the capacitor device 102 from the rest of the semiconductor wafer 104, as known to one of ordinary skill in the art of semiconductor device fabrication. The field oxide region 113 may be formed with shallow trench isolation technology, as known to one of ordinary skill in the art of semiconductor device fabrication.

Referring to FIG. 1B, the thickness of the oxide 108 of the capacitor 102 determines the capacitance of the capacitor 102, and the thickness of the oxide 108 is controlled during fabrication of the capacitor 102. Referring to FIG. 1C, when the oxide 108 of the capacitor 102 is defined on the diffusion region 106, the buffer oxide layer 112 is grown on the semiconductor wafer 104. The oxide 108 of the capacitor 102 is patterned to be over the diffusion region 106 with a photoresist layer 114, as known to one of ordinary skill in the art of integrated circuit fabrication. Referring to FIG. 1D, that part of the buffer oxide layer 112 not covered by the photoresist layer 114 is etched away to define the oxide 108 of the capacitor 102 over the diffusion region 106. Subsequently, the photoresist layer 114 is etched away, and the oxide 108 of the capacitor 102 is grown in a further oxidation process.

Referring to FIGS. 1C, 1D, and 2, during fabrication of the oxide 108 for the capacitor 102, the semiconductor wafer 104 is placed in a bath 202 having a liquid agent 204 that processes oxide regions on the semiconductor wafer 104. For example, the liquid agent 204 may be for etching that part of the buffer oxide layer 112 not covered by the photoresist layer 114 as shown in FIGS. 1C and 1D. Alternatively, the liquid agent 204 may be for cleaning surfaces of the semiconductor wafer 104 after a processing step to remove chemicals or other residue from the surfaces of the semiconductor wafer 104.

Referring to FIG. 3, semiconductor wafers are processed typically in a lot of a plurality of semiconductor wafers including a first semiconductor wafer 302, a second semiconductor wafer 304, a third semiconductor wafer 306, and a fourth semiconductor wafer 308. Referring to FIG. 4, when oxide regions are fabricated on the plurality of semiconductor wafers 302, 304, 306, and 308, those semiconductor wafers are placed on a wafer cassette 402. The wafer cassette 402 holds the semiconductor wafers as the semiconductor wafers are placed into the liquid agent 204 within the bath 202.

The quality of the oxide formed for any integrated circuit device, such as the capacitor 102 for example, determines the performance of that integrated circuit device. If the quality of the oxide is poor, then the integrated circuit device is more likely to fail. Thus, an oxide with high quality is desired. Experiments conducted by the applicants indicate that oxide quality is dependent on the relative positions of the semiconductor wafers with respect to each other when those semiconductor wafers are placed within the wafer cassette 402 for processing within the bath 202.

### SUMMARY OF THE INVENTION

Accordingly, the present invention is a method for fabricating high quality oxides on a plurality of semiconductor wafers by proper positioning of those semiconductor wafers with respect to each other within a wafer cassette for processing within a bath.

Generally, the present invention is a method for fabricating high quality oxides on a plurality of semiconductor wafers with each semiconductor wafer having a predetermined diameter. The method of the present invention includes a step of placing the plurality of semiconductor wafers in a wafer cassette that holds the plurality of semiconductor wafers in a stack configuration. According to the present invention, the plurality of semiconductor wafers within the wafer cassette are spaced with a respective predetermined distance between any two adjacent semiconductor wafers such that a respective ratio of the respective predetermined distance to the predetermined diameter of a semiconductor wafer is at least 0.12. The wafer cassette holding the plurality of semiconductor wafers is then placed within a bath having a liquid agent that processes oxides on the plurality of semiconductor wafers.

In addition, the present invention may further include a step of circulating the liquid agent within the bath when the wafer cassette holding the plurality of semiconductor wafers is placed in the bath and/or a step of vibrating the bath when the wafer cassette holding the plurality of semiconductor wafers is placed in the bath.

The present invention may be used to particular advantage when one of the oxides on the semiconductor wafers is part of a tunnel oxide. In that case, the respective predetermined distance between any two adjacent semiconductor wafers results in the tunnel oxide having higher quality with lower failure rate and with higher charge accumulation before oxide breakdown and with higher breakdown voltage. The tunnel oxide may be part of an integrated circuit, fabricated on each of the semiconductor wafers, having an electrically erasable programming cell.

In addition, the present invention may be used to particular advantage when the liquid agent within the bath is for etching the oxides from the semiconductor wafers or when the liquid agent within the bath is for cleaning surfaces of the semiconductor wafers.

The wafer cassette for holding the plurality of semiconductor wafers may be comprised of a plurality of slots with a respective slot for holding each of the plurality of semiconductor wafers. Each slot within the wafer cassette has a predetermined width. In that case, each of the plurality of semiconductor wafers are placed at least a predetermined number of slots apart from each other within the wafer cassette.

In this manner, by separating the plurality of semiconductor wafers by at least a predetermined distance from each other within the wafer cassette for processing within a bath, higher oxide quality is achieved. With such separation of the plurality of semiconductor wafers, oxides have lower failure rate, higher charge accumulation before breakdown, and higher breakdown voltage. Thus, integrated circuit devices having such oxides in turn have lower failure rate and may operate with higher voltage range before breakdown.

These and other features and advantages of the present invention will be better understood by considering the following detailed description of the invention which is presented with the attached drawings.

### BRIEF DESCRIPTION OF THE DRAWINGS

FIG. 1, including FIGS. 1A, 1B, 1C, and 1D, shows a capacitor with FIG. 1A showing a top view of the capacitor formed on a semiconductor wafer, with FIG. 1B showing a cross sectional view of the capacitor of FIG. 1A, and with FIGS. 1C and 1D showing patterning of an oxide within the capacitor of FIG. 1B;

FIG. 2 shows the semiconductor wafer of FIG. 1 being placed into a bath having a liquid agent for processing of oxide regions on the semiconductor wafer;

FIG. 3 shows a plurality of semiconductor wafers that are typically processed together as a lot of wafers;

FIG. 4 shows a wafer cassette for holding the plurality of semiconductor wafers as the semiconductor wafers are placed into a bath having a liquid agent for processing of oxide regions on the semiconductor wafers;

FIG. 5 shows an example wafer cassette having a plurality of slots with each slot having a predetermined width and with any two adjacent semiconductor wafers being spaced at least a predetermined number of slots away from each other, according to the present invention;

FIG. 6 shows a circuit diagram of an electrically erasable programming cell having a tunnel oxide;

FIG. 7 shows a cross-sectional view of a semiconductor wafer having a photoresist layer for the fabrication of the devices of the electrically erasable programming cell of FIG. 6;

FIG. 8 shows the cross-sectional view of FIG. 7 with removal of the photoresist layer and with further oxide growth; and

FIG. 9 shows a top view of an edge structure capacitor.

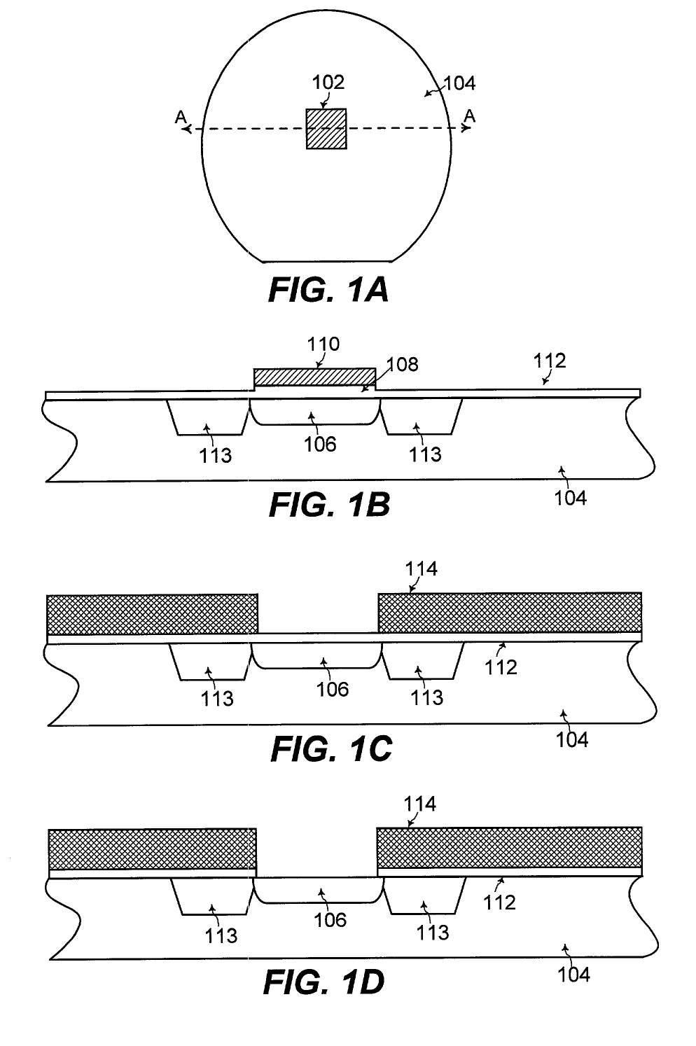

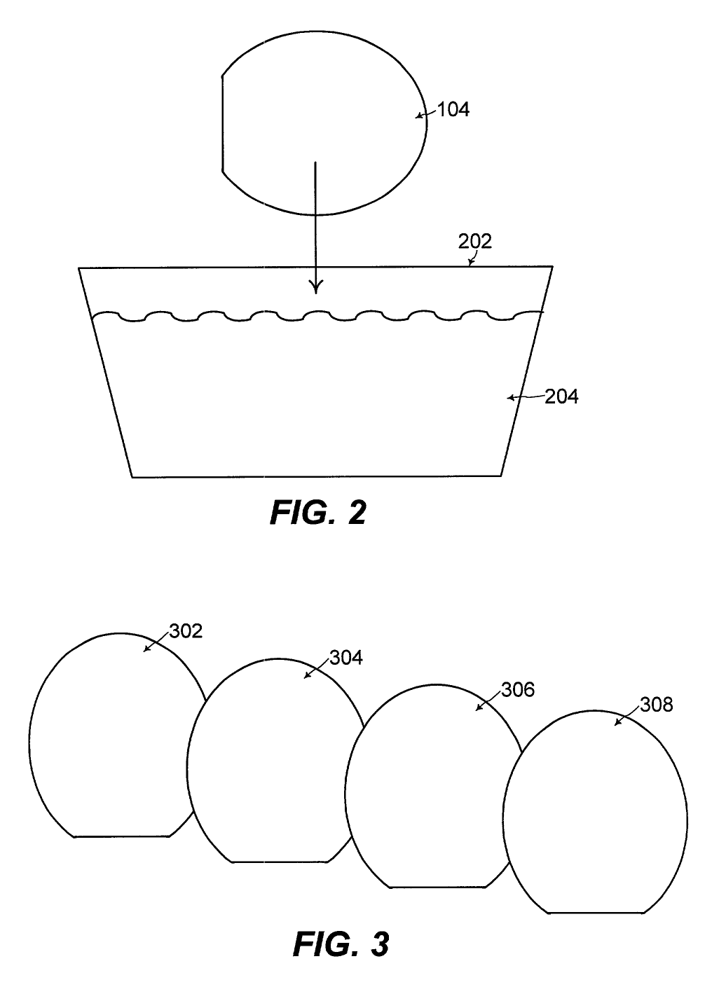

The figures referred to herein are drawn for clarity of illustration and are not necessarily drawn to scale. Moreover, the figures referred to herein focus on a few oxide regions within a larger integrated circuit. Elements having the same reference number in FIGS. 1, 2, 3, 4, 5, 6, 7, 8, and 9 refer to elements having similar structure and function.

### DETAILED DESCRIPTION

The present invention is described with oxides used within capacitors and MOSFETs (Metal Oxide Semiconductor Field Effect Transistors). However, the present invention may be advantageously used for fabrication of oxides in any type of integrated circuit device as would be apparent to one of ordinary skill in the art of integrated circuit fabrication from the description herein.

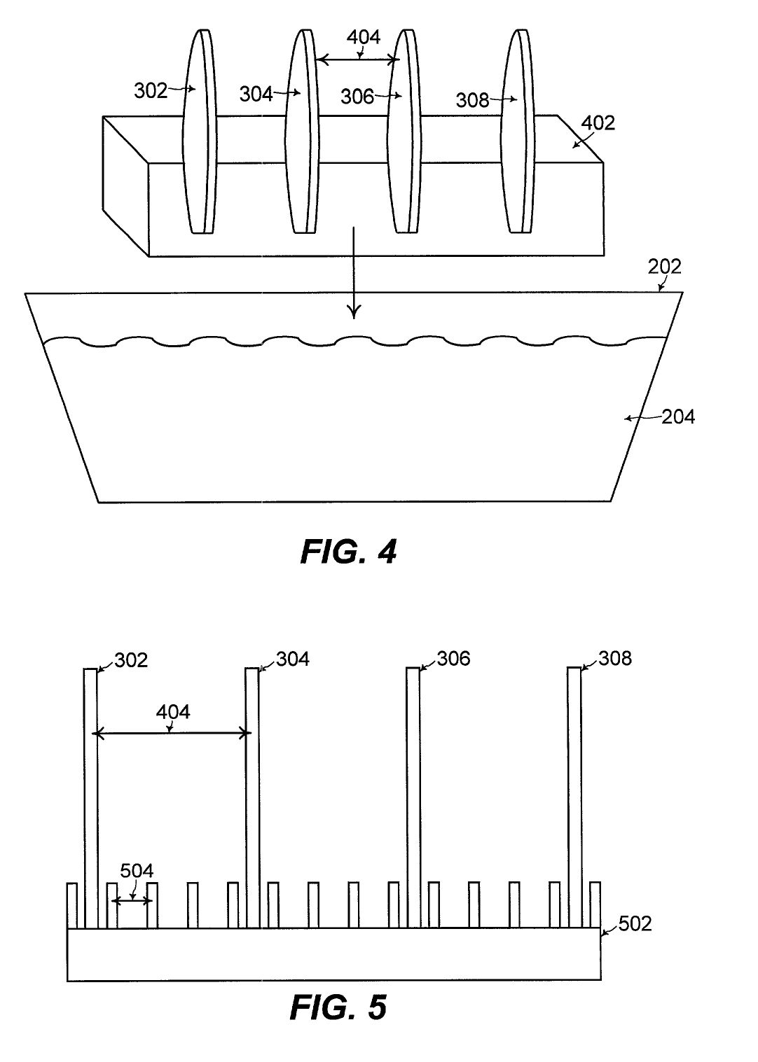

Referring to FIG. 4, the plurality of semiconductor wafers 302, 304, 306, and 308 are placed in the wafer cassette 402 in a stack configuration with the faces of adjacent semiconductor wafers being substantially congruent and parallel to each other. With the present invention, any two adjacent semiconductor wafers within the wafer cassette 402 are spaced with a respective predetermined distance. This distance depends on the diameter of the semiconductor wafers 302, 304, 306, and 308. Each of the semiconductor wafers 302, 304, 306, and 308 have a predetermined diameter.

Experiments by applicants indicate that the oxide quality is substantially improved when any two adjacent semiconductor wafers within the wafer cassette 402 are spaced with a respective predetermined distance (such as distance 404 shown in FIG. 4 for example) such that a respective ratio of the respective predetermined distance to the predetermined diameter of each of the semiconductor wafers is at least 0.12. For example, if the predetermined diameter of each of the semiconductor wafers 302, 304, 306, and 308 is eight inches (i.e., 20.32 centimeters), then the respective predetermined distance between any two adjacent semiconductor wafers within the wafer cassette 402 is at least 0.96 inches (i.e., 2.44 centimeters).

Referring to FIG. 1B, in experiments by the applicants, oxide quality was determined by fabrication of test capacitors similar to the capacitor structure 102 of FIG. 1B on the semiconductor wafers. Each of the test capacitors have a small area of 1×10⁻⁵ cm² (squared centimeters). Such a small area ensures that intrinsic properties of the oxide quality are measured instead of extrinsic factors such as oxide defects or contamination. Oxide quality is measured by determining whether the capacitor having the oxide is functional (i.e., the failure rate of the capacitors). In addition, oxide quality is determined by measuring the amount of charge accumulation on the oxide before oxide breakdown and by measuring the breakdown voltage before oxide breakdown. Such measurement techniques are known to one of ordinary skill in the art of integrated circuit fabrication.

Referring to FIG. 4, in the experiments by the applicants, capacitors are fabricated on the semiconductor wafers 302, 304, 306, and 308, and the distance between any two adjacent semiconductor wafers within the wafer cassette 402 is varied. The oxide quality within those capacitors formed with various distances between any two adjacent semiconductor wafers within the wafer cassette 402 is then determined. The oxide quality improves substantially when the respective distance between any two adjacent semiconductor wafers within the wafer cassette 402 is a minimum distance such that a respective ratio of the respective distance to the predetermined diameter of each of the semiconductor wafers is at least 0.12.

With such separation between any two adjacent semiconductor wafers, the wafer cassette 402 holding the semiconductor wafers 302, 304, 306, and 308 is placed into the bath 202. Within the bath 202, the oxides on the semiconductor wafers 302, 304, 306, and 308 are processed by immersion within the liquid agent 204. For example, the liquid agent 204 may be for etching the oxide regions from the semiconductor wafers or the liquid agent may be for cleaning surfaces of the semiconductor wafers.

Experiments by applicants indicate that higher quality oxide results when the semiconductor wafers are processed within the bath 202 with a respective distance between any two adjacent semiconductor wafers within the wafer cassette 402 being a minimum distance such that a respective ratio of the respective distance to the predetermined diameter of each of the semiconductor wafers is at least 0.12. The higher quality oxide is indicated as measured by a lower device failure rate, a higher charge accumulation before oxide breakdown, and a higher breakdown voltage.

Referring to FIG. 5, typical wafer cassettes, used for holding semiconductors wafers for processing within a bath, have a plurality of slots with each slot holding a respective semiconductor wafer, as known to one of ordinary skill in the art of integrated circuit fabrication. Such a wafer cassette 502 in FIG. 5 has a plurality of slots with the width of each slot (as shown by line 504 in FIG. 5) being 0.64 cm (centimeters). With such a wafer cassette 502 and with the predetermined diameter of the plurality of semiconductor wafers 302, 304, 306, and 308 being eight inches, experiments by applicants indicate that higher quality oxide results when the semiconductor wafers are processed within the bath 202 with any two adjacent semiconductor wafers being placed at least four slots apart from each other as shown in FIG. 5.

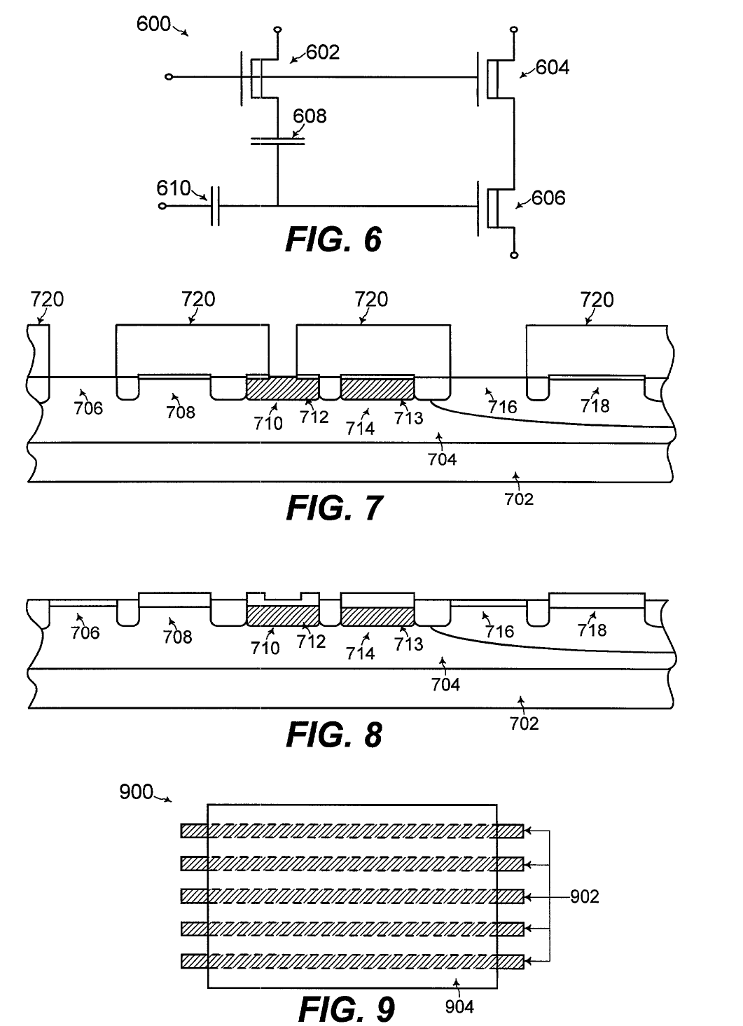

The oxide quality from having proper distance between semiconductor wafers within a wafer cassette is especially affected for tunnel oxides as used in (EEPLDs) Electrically Erasable Programmable Logic Devices available from Vantis Corporation in Sunnyvale, Calif. Referring to FIG. 6, an electrically erasable programming cell 600 used in such an EEPLD includes a programming transistor 602, a read transistor 604, and a sense transistor 606. The electrically erasable programming cell 600 also includes a tunnel oxide 608 and a control gate 610. The operation of the electrically erasable programming cell 600 as used in an EEPLD is known to one of ordinary skill in the art of electronic systems, and a manual describing such operation is available from Vantis Corporation in Sunnyvale, Calif.

Referring to FIG. 7, a cross sectional view of an integrated circuit fabricated on a semiconductor wafer 702 with a tunnel oxide is shown. An epitaxial layer 704 is deposited on the semiconductor wafer 702. A first region 706 in the epitaxial layer 704 forms a gate for a low voltage NMOSFET (N-channel Metal Oxide Semiconductor Field Effect Transistor), and a second region 708 in the epitaxial layer 704 forms a gate for a high voltage NMOSFET (N-channel Metal Oxide Semiconductor Field Effect Transistor).

The first region 706 for a low voltage NMOSFET has a thinner oxide grown thereon than the thickness of the oxide grown on the second region 708 for the high voltage NMOSFET. The thickness of the oxide on the first region 706 for a low voltage NMOSFET may be approximately 80 Å (Angstroms), and the thickness of the oxide on the second region 708 for a high voltage NMOSFET may be approximately 150 Å (Angstroms).

A third region 710 in the epitaxial layer 704 has tunnel oxide grown thereon. The third region 710 has a doped region 712 that provides a source of electrons. The thickness of the tunnel oxide grown on the third region 710 is approximately 95 Å (Angstroms). A fourth region 714 in the epitaxial layer 704 forms a control gate similar to the control gate 610 in FIG. 6. The fourth region 714 has a doped region 713 which is typically doped with the same type of dopant as the doped region 712 under the tunnel oxide. The thickness of the oxide grown on the fourth region 714 for the control gate is approximately 150 Å (Angstroms).

A fifth region 716 in the epitaxial layer 704 forms a gate for a low voltage PMOSFET (P-channel Metal Oxide Semiconductor Field Effect Transistor), and a sixth region 718 in the epitaxial layer 704 forms a gate for a high voltage PMOSFET (P-channel Metal Oxide Semiconductor Field Effect Transistor).

The fifth region 716 for a low voltage PMOSFET has a thinner oxide grown thereon than the thickness of the oxide grown on the sixth region 718 for the high voltage PMOSFET. The thickness of the oxide on the fifth region 716 for a low voltage PMOSFET may be approximately 80 Å (Angstroms), and the thickness of the oxide on the sixth region 718 for a high voltage PMOSFET may be approximately 150 Å (Angstroms).

The first region 706, the second region 708, the third region 710, the fourth region 714, the fifth region 716, and the sixth region 718 within the epitaxial layer 704 are separated from each other by trench field oxides, as known to one of ordinary skill in the art of integrated circuit fabrication. Referring to FIG. 7, a photoresist layer 720 is deposited on the epitaxial layer 704 to etch oxides from the first region 706 for the low voltage NMOSFET, from the third region 710 for the tunnel oxide, and from the fifth region 716 for the low voltage PMOSFET. A plurality of semiconductor wafers each holding an integrated circuit of the cross section of FIG. 7 are placed into a wafer cassette for etching the oxides in a bath as shown in FIG. 4.

Referring to FIG. 8, after the oxide is thus etched in a bath, the photoresist layer 720 is removed. The plurality of semiconductor wafers each holding an integrated circuit of the cross section of FIG. 7 may be placed into a wafer cassette for removing the photoresist layer 720 in a bath as shown in FIG. 4.

After the photoresist layer 720 is removed, oxide is additionally grown on the first region 706, the second region 708, the third region 710, the fourth region 714, the fifth region 716, and the sixth region 718. Experiments by applicants indicate that the quality of the tunnel oxide on the third region 710 is especially affected by proper spacing of the plurality of semiconductor wafers in the wafer cassette. A higher quality in the tunnel oxide results when the semiconductor wafers are processed within the bath 202 with a respective distance between any two adjacent semiconductor wafers within the wafer cassette 402 being a minimum distance such that a respective ratio of the respective distance to the predetermined diameter of each of the semiconductor wafers is at least 0.12.

With such spacing, the failure rate of the tunnel oxide decreases from approximately 50% with closer semiconductor wafer spacing within the wafer cassette to substantially 0% with the proper distance between the semiconductor wafers within the wafer cassette. In addition, the tunnel oxide has higher charge accumulation before oxide breakdown and higher breakdown voltage with the proper distance between the semiconductor wafers within the wafer cassette.

Referring to FIG. 9, the top view of an edge structure PMOS (P-channel Metal Oxide Semiconductor) capacitor 900 shows a plurality of p-type doped regions 902. An oxide 904 is deposited on top of the plurality of p-type doped regions 902 as shown in FIG. 9, and a polysilicon layer is then deposited on top of the oxide 904 (not shown in FIG. 9 for clarity of illustration). The plurality of p-type doped regions 902 are coupled together to form one node of the edge structure PMOS capacitor 900, and the polysilicon layer forms the other node of the edge structure PMOS capacitor 900. Such edge structures are used to determine the viability of fabricating fine line structures such as each of the p-type doped regions 902 for an integrated circuit fabrication process.

Experiments by applicants indicate that the quality of the oxide 904 in the edge structure PMOS capacitor 900 is especially affected by proper spacing of the plurality of semiconductor wafers in the wafer cassette. A higher quality in the oxide of the edge structure PMOS capacitor 900 results when the semiconductor wafers are processed within the bath 202 with a respective distance between any two adjacent semiconductor wafers within the wafer cassette 402 being a minimum distance such that a respective ratio of the respective distance to the predetermined diameter of each of the semiconductor wafers is at least 0.12.

With such spacing, the failure rate of the oxide of the edge structure PMOS capacitor 900 decreases from approximately 45% with closer semiconductor wafer spacing within the wafer cassette to substantially 0% with the proper distance between the semiconductor wafers within the wafer cassette. In addition, the oxide of the edge structure PMOS capacitor 900 has higher charge accumulation before oxide breakdown and higher breakdown voltage with the proper distance between the semiconductor wafers within the wafer cassette.

In this manner, the present invention ensures growth of high quality oxides by proper spacing between the plurality of semiconductor wafers in a wafer cassette that is placed in a bath for processing of the oxides. For increased throughput of semiconductor wafer processing, the distance between the semiconductor wafers is typically minimized such that more semiconductor wafers may be processed within a wafer cassette.

However, with the present invention, a minimum distance between any two adjacent semiconductor wafers within a wafer cassette ensures higher quality oxides. Thus, for optimum throughput and yet high quality oxides, the minimum distance between any two adjacent semiconductor wafers required for high quality oxides is typically used. Any higher distance between any two adjacent semiconductor wafers may be a waste of space in the wafer cassette. The minimum distance that is required is such that a ratio of the distance between any two adjacent semiconductor wafers to the predetermined diameter of a semiconductor wafer is at least 0.12. Thus, for higher diameter semiconductor wafers, the distance between any two adjacent semiconductor wafers increases. Referring to FIG. 4, adequate distance between the semiconductor wafers ensures that proper amounts of chemicals within the liquid agent 204 of the bath 202 reach all areas of the semiconductor wafers for a thorough processing of the oxides on the semiconductor wafers within the bath 202.

Aside from controlling the distance between any two adjacent semiconductor wafers within a wafer cassette, other steps may further ensure high quality oxides. Referring to FIG. 4, the liquid agent 204 may be circulated within the bath 202 when the wafer cassette 402 holding the plurality of semiconductor wafers is placed in the bath 202 for processing. Additionally, the liquid agent 204 may be vibrated within the bath 202 when the wafer cassette 402 holding the plurality of semiconductor wafers is placed in the bath 202 for processing. Such circulation and vibration of the liquid agent 204 further ensures that proper amounts of chemicals within the liquid agent 204 of the bath 202 reach all areas of the semiconductor wafers for a thorough processing of the semiconductor wafers within the bath 202. Techniques for circulation and vibration of the liquid agent 204 in the bath 202 are known to one of ordinary skill in the art of integrated circuit fabrication.

The foregoing is by way of example only and is not intended to be limiting. For example, the present invention is described with respect to oxides within capacitors. However, the present invention may be advantageously used for fabrication of high quality oxides in any type of integrated circuit device, as would be apparent to one of ordinary skill in the art of integrated circuit fabrication from the description herein. The present invention may also be practiced for any type of liquid agent 204 for any type of integrated circuit fabrication processing step, as would be apparent to one of ordinary skill in the art of integrated circuit fabrication from the description herein. In addition, the present invention may be practiced with any type of wafer cassettes used for holding a plurality of semiconductor wafers for processing within a bath, aside from the examples illustrated in FIGS. 4 and 5.

Furthermore, as will be understood by those skilled in the art, the integrated circuit structures described herein may be made or used in the same way regardless of their position and orientation. Accordingly, it is to be understood that terms and phrases such as “on top of” as used herein refer to the relative location and orientation of various portions of the structures with respect to one another, and are not intended to suggest that any particular absolute orientation with respect to external objects is necessary or required.

The invention is limited only as defined in the following claims and equivalents thereof.

We claim:

1. A method for fabricating high quality oxides on a plurality of semiconductor wafers, each semiconductor wafer having a predetermined diameter, the method including the steps of:
A. placing said plurality of semiconductor wafers in a wafer cassette that holds said plurality of semiconductor wafers in a stack configuration;
B. spacing said plurality of semiconductor wafers within said wafer cassette with a respective predetermined distance between any two adjacent semiconductor wafers such that a respective ratio of said respective predetermined distance to said predetermined diameter is at least 0.12; and
C. placing said wafer cassette holding said plurality of semiconductor wafers within a bath having a liquid agent that processes oxides on said plurality of semiconductor wafers.

2. The method of claim 1, further including the step of:
circulating said liquid agent within said bath when said wafer cassette holding said plurality of semiconductor wafers is placed in said bath.

3. The method of claim 1, further including the step of:
vibrating said bath when said wafer cassette holding said plurality of semiconductor wafers is placed in said bath.

4. The method of claim 1, wherein one of said oxides on said semiconductor wafers is part of a tunnel oxide and wherein said respective predetermined distance between any two adjacent semiconductor wafers results in said tunnel oxide having higher quality with lower failure rate and with higher charge accumulation before oxide breakdown and with higher breakdown voltage.

5. The method of claim 4, wherein said tunnel oxide is part of an integrated circuit, fabricated on each of said semiconductor wafers, having an electrically erasable programming cell.

6. The method of claim 1, wherein one of said oxides on said semiconductor wafers is part of a low voltage PMOS (P-channel Metal Oxide Semiconductor) edge structure capacitor and wherein said respective predetermined distance between any two adjacent semiconductor wafers results in said oxide within said low voltage PMOS edge structure capacitor having higher quality with lower failure rate and with higher charge accumulation before oxide breakdown and with higher breakdown voltage.

7. The method of claim 1, wherein said liquid agent within said bath is for etching said oxides from said semiconductor wafers.

8. The method of claim 1, wherein said liquid agent within said bath is for cleaning surfaces of said semiconductor wafers.

9. The method of claim 1, wherein said predetermined diameter, of each of said plurality of semiconductor wafers, is eight inches, and wherein said respective predetermined distance between any two adjacent semiconductor wafers within said wafer cassette is at least 2.44 cm (centimeters).

10. The method of claim 9, wherein said wafer cassette for holding said plurality of semiconductor wafers has a respective slot for holding a semiconductor wafer, and wherein a distance between any two adjacent slots is 0.64 cm (centimeters), and wherein each of said plurality of semiconductor wafers are placed at least four slots apart from each other within said wafer cassette.

11. A method for fabricating high quality oxides on a plurality of semiconductor wafers, each semiconductor wafer having a predetermined diameter of about eight inches, the method including the steps of:
placing said plurality of semiconductor wafers in a wafer cassette that holds said plurality of semiconductor wafers in a stack configuration, and wherein said wafer cassette has a respective slot for holding a semiconductor wafer, and wherein a distance between any two adjacent slots is 0.64 cm (centimeters);
spacing said plurality of semiconductor wafers within said wafer cassette such that any two adjacent semiconductor wafers within said wafer cassette are at least four slots apart from each other;
placing said wafer cassette holding said plurality of semiconductor wafers within a bath having a liquid agent that processes oxides on said plurality of semiconductor wafers, wherein said liquid agent within said bath is for one of etching said oxides from said semiconductor wafers and of cleaning surfaces of said semiconductor wafers;
circulating said liquid agent within said bath when said wafer cassette holding said plurality of semiconductor wafers is placed in said bath;
vibrating said bath when said wafer cassette holding said plurality of semiconductor wafers is placed in said bath;
wherein said oxide on said semiconductor wafer is part of a tunnel oxide and wherein said spacing between any two adjacent semiconductor wafers within said wafer cassette results in said tunnel oxide having higher quality with lower failure rate and with higher charge accumulation before oxide breakdown and with higher breakdown voltage; and
wherein said tunnel oxide is part of an integrated circuit, fabricated on each of said semiconductor wafers, having an electrically erasable programming cell.
